(19) United States
(12) Patent Application Publication
(10) Pub. No.: US 2016/0133817 A1
(43) Pub. Date: May 12, 2016

(54) FUNCTIONAL AND DURABLE THERMOELECTRIC DEVICES AND SYSTEMS

(71) Applicant: Tempronics, Inc., Tucson, AZ (US)

(72) Inventors: Tarek Makansi, Tucson, AZ (US); John Latimer Franklin, Tucson, AZ (US); Kevin Forbes, Tucson, AZ (US); Kevin Geisler, Tucson, AZ (US); Jose Santos Dominguez, Bisbee, AZ (US); Michael Sato, Tucson, AZ (US); Robert Fogoros, Green Valley, AZ (US); Richard Myers, Oro Valley, AZ (US)

(21) Appl. No.: 14/934,757

(22) Filed: Nov. 6, 2015

Related U.S. Application Data
(60) Provisional application No. 62/076,042, filed on Nov. 6, 2014.
(60) Provisional application No. 62/133,215, filed on Mar. 13, 2015.
(60) Provisional application No. 62/172,751, filed on Jun. 8, 2015.
(60) Provisional application No. 62/191,207, filed on Jul. 10, 2015.

(51) Int. Cl. H01L 35/32; H01L 35/08

(52) U.S. Cl. CPC H01L 35/325; H01L 35/08

(57) ABSTRACT

The present disclosure provides a thermoelectric device comprising a panel comprising an electrically and thermally insulating material, and a thermoelectric string comprising a plurality of thermoelectric elements mounted on a strain relief element within the panel. The thermoelectric elements may comprise an n-type thermoelectric element and a p-type thermoelectric element electrically coupled to one another in series. The thermoelectric string may be (i) compacted in cross section inside the panel and (ii) expanded in cross section outside the panel. The strain relief element may permit the thermoelectric string to be movable in proximity to the strain relief element.

### CROSS-REFERENCE

This application claims priority to U.S. Provisional Application Ser. No. 62/076,042, filed Nov. 6, 2014, U.S. Provisional Application Ser. No. 62/133,215, filed Mar. 13, 2015, U.S. Provisional Application Ser. No. 62/172,751, filed Jun. 8, 2015, and U.S. Provisional Application Ser. No. 62/191,207, filed Jul. 10, 2015, each of which is entirely incorporated herein by reference.

### BACKGROUND

The thermoelectric effect is the conversion of temperature differences to electric voltage and vice versa. A thermoelectric device may create voltage when there is a temperature gradient across the thermoelectric device, such as when there is a different temperature on each side of the thermoelectric device. Conversely, when a voltage is applied to the thermoelectric device, it may create a temperature difference. An applied temperature gradient may cause charge carriers in the thermoelectric device to diffuse from a hot side to a cold side of the thermoelectric device.

The term “thermoelectric effect” encompasses the Seebeck effect, Peltier effect and Thomson effect. Solid-state cooling and power generation based on thermoelectric effects typically employ the Seebeck effect or Peltier effect for power generation and heat pumping. The utility of such conventional thermoelectric devices is, however, typically limited by their low coefficient-of-performance (COP) (for refrigeration applications) or low efficiency (for power generation applications).

Thermoelectric modules may contain densely packed elements spaced apart by 1-3 mm. Up to 256 such elements may be connected in an array that is 2×2 inches (5.08×5.08 cm) in area. When these modules are deployed, large and heavy heat sinks and powerful fans may be required to dissipate or absorb heat on each side. Small elements with low resistance may allow larger current (I) to flow before the resistive heat (I²R) generated destroys the thermoelectric cooling. The use of short elements for maximum cooling capacity results in the hot and cold side circuit boards being close together. This proximity may result in the high density.

To achieve low density packing of thermoelectric elements, the elements may be laterally spaced on the boards, but then the backflow of heat conducted and radiated through the air between the elements limits the overall performance. Some designs may require evacuating the module interior to reduce heat backflow due to air conduction, but vacuum cavities require expensive materials and are prone to leaks. Vacuum materials (like glass and Kovar™) are also hard and easily broken when thin enough to limit their own backflow of heat. Broken glass can lead to safety issues when these modules are used in seat cushions, automobiles, and other environments.

Another problem in spreading out thermoelectric elements is that the rigid connection of elements over large distances causes them to rupture due to sheer stress upon thermal expansion of the hot side relative to the cold side. To solve this problem, other designs have been proposed that use a flexible plastic such as polyimide for the circuit boards, but these materials are too porous to maintain a vacuum.

Another disadvantage of the prior art design of thermoelectric modules is that the high density of heat moved to the hot side may result in a temperature gradient through the heat sink, and this temperature change may subtract from the overall cooling that the module can achieve. In particular, traditional thermoelectric products may not be able to reach true refrigeration temperature because of this temperature gradient.

In addition, because some traditional thermoelectric modules may be placed in a solder reflow oven during assembly, only high-temperature materials may be used. Unfortunately, many desired uses of cooling and heating involve close or direct contact with the human body, for which soft materials, such as cushions, cloths, and flexible foam may be preferred, but these materials cannot withstand the high temperatures of a solder reflow oven.

### SUMMARY

Thermoelectric devices can be as efficient, or even more efficient, than vapor compression cooling systems when the temperature change is 10° C. or less. The total energy savings of the central A/C or heating system plus the local thermoelectric systems can be 30% or more for such a combination, but the unwieldy implementation of some traditional thermoelectric modules inhibits their use for this purpose. As such, recognized herein is the need to deploy thermoelectric technology for local heating and cooling of occupied spaces and thereby reduce the overall energy consumption needed for such deployment, as well as the need for a variety of insulating panels to be safely and comfortably improved with thermoelectric capability, such as seat cushions (e.g., car seat, truck seat, boat seat, or airplane seat), mattresses, pillows, blankets, ceiling tiles, office/residence walls or partitions, under-desk panels, electronic enclosures, building walls, solar panels, refrigerator walls, freezer walls within refrigerators, or crisper walls within refrigerators. In addition, because thermoelectric modules may be used for power generation, recognized herein is the need for a low-cost electrical power generation capability that can supply power 24 hours per day, 7 days per week, and 365 days per year and only tap renewable energy sources.

The present disclosure provides thermoelectric modules comprising thermoelectric strings, which may be used to transfer heat to or from objects. When connected together, thermoelectric strings may be assembled in an array formation.

The present disclosure provides methods of producing thermoelectric strings and integrating thermoelectric strings within consumer products. Additionally, designs of thermoelectric strings and devices that include one or more thermoelectric strings are provided.

The present disclosure describes advancements to a connected series of thermoelectric strings, such as thermoelectric panels, that improves durability; advancements in the integration of the thermoelectric strings and/or thermoelectric panels with surfaces that improve smoothness and softness of a consumer product; and advancements in air flow systems that improve manufacturability and thermal performance of thermoelectric strings and/or thermoelectric panels. Thermoelectric strings and thermoelectric panels as discussed herein may be used in many products and applications, such as seats, seat backs, seat tops, beds, bed tops, wheelchair cushions, hospital beds, animal beds, and office chairs.

The present disclosure also provides examples of a T-shaped (or substantially T-shaped) configuration of a thermoelectric string. While some examples of thermoelectric strings may be bent when inserted into a desired material to be heated and/or cooled, examples discussed herein provide links of the thermoelectric string that may be connected to a strain relief at a 45 degree to 90-degree angle. By connecting the links of the thermoelectric string to the strain relief at a 45 degree to 90-degree angle rather than bending the links, embodiments described herein lessen and/or eliminate the need for the wires to be bent at varying degrees. Additionally, minimizing the bending of the wires of the links may be used to improve the durability and the thermoelectric string.

Additionally, the disclosure also provides examples of different materials that may be placed between links of a thermoelectric string and a surface of a seat, bed, or other product. In some examples, materials that may be placed between links of a thermoelectric string may be used to improve the smoothness or softness or both smoothness and softness of the feel of the surface while also maintaining adequate thermal transmission. Examples of materials that may be placed between links of a thermoelectric string include polyester fill material, rubber material, lamb's wool, corrugated textiles, and non-slip pads.

In additional embodiments, air flow systems are provided that allow for easy integration of thermoelectric strings with product manufacturing processes. Additionally, air flow systems may also be used to accommodate moving parts of products, such as a seat cushion or a bed. In some examples, a flexible and sealed spacer mesh duct may be combined with linear air channels to provide an air path to the underside of a seat or bed cushion or the backside of a seatback cushion. In additional examples, a foam material may be used for an air duct, allowing for flexibility and noise abatement. In further examples, flexible tubing may be used to reach movable portions of a seat cushion, including a thigh support area that may move forward and backward. Flexible tubing may also be used to reach side-bolster support areas that may move inward and outward.

An aspect of the present disclosure provides a thermoelectric device, comprising a panel comprising an electrically and thermally insulating material; and a thermoelectric string comprising a plurality of thermoelectric elements mounted on a strain relief element within the panel, wherein the thermoelectric elements comprise an n-type thermoelectric element and a p-type thermoelectric element electrically coupled to one another in series, wherein the thermoelectric string is (i) compacted in cross section inside the panel and (ii) expanded in cross section outside the panel, and wherein the strain relief element permits the thermoelectric string to be movable in proximity to the strain relief element.

In some embodiments, the thermoelectric string is secured to the panel in the absence of an adhesive.

In some embodiments, the thermoelectric device further comprises an additional strain relief element within the panel, wherein the thermoelectric string is mounted on the additional strain relief element. In some embodiments, the thermoelectric string is threaded into the additional strain relief element through an opening to permit the thermoelectric string to rotate with respect to the additional strain relief element. In some embodiments, the thermoelectric device further comprises a plurality of additional thermoelectric elements mounted on the additional strain relief element, wherein the additional thermoelectric elements comprise an n-type thermoelectric element and a p-type thermoelectric element electrically coupled to one another in series, and wherein the additional thermoelectric elements are in electrical communication with the plurality of thermoelectric elements mounted on the strain relief panel.

In some embodiments, the n-type thermoelectric element is electrically coupled to the p-type thermoelectric element through a stranded wire in the panel. In some embodiments, the strain relief element is removable from the panel.

In some embodiments, the panel is elongated. In some embodiments, the thermoelectric string comprises stranded wires with opposing ends that are each terminated by a termination element to maintain compaction of the stranded wires. In some embodiments, the opposing ends are terminated with ferrule or splice bands. In some embodiments, the stranded wires are attached to the plurality of thermoelectric elements and/or the strain relief element with solder.

In some embodiments, the thermoelectric string is threaded into the strain relief element through an opening in the strain relief element, which opening permits the thermoelectric string to rotate with respect to the strain relief element. In some embodiments, the strain relief element comprises glass fiber, epoxy, and/or composite material.

In some embodiments, the thermoelectric device further comprises an intermediate pad adjacent to the panel and a cover adjacent to the intermediate pad. In some embodiments, the intermediate pad has an uncompressed thickness between about 5 millimeters and 10 millimeters. In some embodiments, the intermediate pad comprises viscoelastic foam, polyester fibers and/or carbon particles. In some embodiments, the carbon particles are diamond particles. In some embodiments, the intermediate pad is a flexible embossed sheet. In some embodiments, the flexible embossed sheet comprises rubber, neoprene, urethane, and/or silicone. In some embodiments, centers of the flexible embossed sheet are separated by a distance between about 3 millimeters and 10 millimeters. In some embodiments, the intermediate pad is formed of wool. In some embodiments, the intermediate pad is comprised of a textile sheet with pre-stretched elastic fibers. In some embodiments, the intermediate pad is comprised of a lattice with walls and voids. In some embodiments, the voids are square or square-like with side lengths between about 3 millimeters and 10 millimeters. In some embodiments, the thermoelectric device further comprises an additional layer between the intermediate layer and the cover, wherein the additional layer permits the cover to move relative to the intermediate layer.

In some embodiments, the strain relief element is disposed in a trench among a plurality of trenches in the panel. In some embodiments, each of the plurality of trenches has a cross-section that is circular, triangular, semicircular, square or rectangular.

In some embodiments, the strain relief element is disposed in a linear slit among a plurality of slits in the panel. In some embodiments, the linear slit is at an acute or right angle relative to a surface of the panel.

In some embodiments, the thermoelectric device further comprises a fluid flow system comprising channels adjacent to the panel. In some embodiments, the thermoelectric device further comprises a bagged and flexible spacer mesh for routing a fluid to the channels. In some embodiments, the thermoelectric device further comprises a fan at an end of the bagged and flexible spacer mesh. In some embodiments, the fluid flow system is mounted below or behind a set. In some embodiments, the thermoelectric device further comprises a foam tube in fluid communication with the channels. In some embodiments, the thermoelectric device further comprises a plurality of thermoelectric strings including the thermoelectric string in the channels, which plurality of thermoelectric strings includes wires spread out on a surface of the panel.

In some embodiments, the thermoelectric device further comprises a plurality of thermoelectric strings including the thermoelectric string, wherein each of the plurality of thermoelectric strings comprises a plurality of thermoelectric elements mounted on a given strain relief element within the panel.

In some embodiments, the panel comprises holes that are directed from a first side of the panel to a second side of the panel, wherein the second side is adjacent to an air flow layer, wherein the holes permit a fluid to flow from the first side to the second side to mix with air in the air flow layer.

Another aspect of the present disclosure provides a thermoelectric system comprising one or more thermoelectric devices as described above or elsewhere herein.

Another aspect of the present disclosure provides method for forming a thermoelectric device or system as described above or elsewhere herein. In some embodiments, a method for forming a thermoelectric device or system comprises (a) generating a trench or linear slit in a panel comprising an electrically and thermally insulating material; and (b) providing a thermoelectric string comprising a plurality of thermoelectric elements mounted on a strain relief element within the trench or linear slit, wherein the thermoelectric elements comprise an n-type thermoelectric element and a p-type thermoelectric element electrically coupled to one another in series, wherein the thermoelectric string is (i) compacted in cross section inside the panel and (ii) expanded in cross section outside the panel, and wherein the strain relief element permits the thermoelectric string to be movable in proximity to the strain relief element.

In some embodiments, (b) comprises securing the thermoelectric string to the panel without the use of an adhesive. In some embodiments, (a) comprises generating a plurality of trenches or linear slits in the panel, which plurality of trenches or linear slits includes the trench or linear slit. In some embodiments, (b) comprises providing a plurality of thermoelectric strings including the thermoelectric string, wherein each of the plurality of thermoelectric strings comprises a plurality of thermoelectric elements mounted on a given strain relief element within the panel.

In some embodiments, the method further comprises (i) providing an intermediate pad adjacent to the panel, and (ii) providing a cover adjacent to the intermediate pad. In some embodiments, (b) comprises (i) mounting the thermoelectric elements on the strain relief element and (ii) inserting the strain relief element in the panel.

In some embodiments, (a) comprises removing a select portion of the panel to generate the trench or linear slit, and (b) comprises providing a portion of the thermoelectric string in the trench or panel. In some embodiments, the method further comprises replacing the selection portion over the portion of the thermoelectric string provided in the trench or linear slit.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings (also “figure” and “FIG.” herein), of which:

FIGS. 1A-1C show views of a T-shaped (or substantially T-shaped) configuration for a thermoelectric string wherein the lead-in and lead-out links are attached to the strain relief at a 90-degree angle, in accordance with some embodiments of the present disclosure. FIG. 1A illustrates a side view of a T-shaped configuration for a thermoelectric string; FIG. 1B illustrates an underneath view of a T-shaped configuration for a thermoelectric string; and FIG. 1C illustrates a top view of a T-shaped configuration for a thermoelectric string;

FIGS. 2A-2C show views of a diamond particle-infused viscoelastic foam as a plus pad, in accordance with some embodiments of the present disclosure. FIG. 2A illustrates a diamond-infused viscoelastic foam pad that is 6 millimeters (mm) in thickness; FIG. 2B illustrates an apparatus for measuring hand feel and thermal transmission; and FIG. 2C illustrates the integration of a foam pad (e.g., viscoelastic foam pad) in an automotive seat cover;

FIGS. 3A-3B show views of a continence pad of polyester fill and an apparatus for testing its functionality as a pad between a leather seat cover and the seat surface containing a thermoelectric string, in accordance with some embodiments of the present disclosure. FIG. 3A illustrates a continence pad; and FIG. 3B illustrates an apparatus for measuring hand feel and thermal transmission;

FIGS. 4A-4B show views of an embossed sheet (e.g., rubber sheet) and an apparatus for testing its functionality as a pad between a leather seat cover and the seat surface containing a thermoelectric string, in accordance with some embodiments of the present disclosure. FIG. 4A illustrates an embossed pad; and FIG. 4B illustrates an apparatus for measuring hand feel and thermal transmission;

FIGS. 5A-5B show views of a loose bunch of lamb's wool and an apparatus for testing its functionality as a pad between a leather seat cover and the seat surface containing a thermoelectric string, in accordance with some embodiments of the present disclosure. FIG. 5A illustrates lamb's wool as an example of a plus pad; and FIG. 5B illustrates an apparatus for measuring hand feel and thermal transmission;

FIGS. 6A-6B show views of a stretchy corrugated textile and an apparatus for testing its functionality as a pad between a leather seat cover and the seat surface containing a thermoelectric string, in accordance with some embodiments of the present disclosure. FIG. 6A illustrates a stretched corrugated fabric as an example of a plus pad; and FIG. 6B illustrates an apparatus for measuring hand feel and thermal transmission;

FIGS. 7A-7B show views of a non-slip pad and an apparatus for testing its functionality as a pad between a leather seat cover and the seat surface containing a thermoelectric string, in accordance with some embodiments of the present disclosure. FIG. 7A illustrates a non-slip pad as a plus pad; and FIG. 7B illustrates an apparatus for measuring hand feel and thermal transmission;

FIGS. 8A-8D show views of a method of cutting strips and forming trenches in the foam prior to insertion of the thermoelectric string, and then re-inserting the strips to cover the thermoelectric string, in accordance with some embodiments of the present disclosure. FIG. 8A illustrates strips cut to form trenches and thermoelectric strings inserted therein; FIG. 8B illustrates cut strips re-inserted with adhesive; FIG. 8C illustrates a close up view of cut strips re-inserted into foam; and FIG. 8D illustrates re-glued foam with angled slits between links to prevent a short circuit;

FIGS. 9A-9C show views of linear air channels for air flow along the heat exchangers is mated with a sealed spacer mesh material that allows the air flow path to be routed underneath the seat and a fan mount for a fan to pull the air, in accordance with some embodiments of the present disclosure. FIG. 9A illustrates parts including a spacer mesh, plastic sheeting, and distributed thermoelectric panel; FIG. 9B illustrates plastic sheeting assembled between two foam layers; and FIG. 9C illustrates a final assembly of a plastic sheeting wrapped around airflow layer and spacer mesh and sealed;

FIG. 10 shows a foam tube that may allow for a flexible and long air path between a fan duct and the exit duct, in accordance with some embodiments of the present disclosure;

FIGS. 11A-11B show views of a fan and duct assembly with flexible tubes to pull air from multiple sections of the seat, including moving sections, in accordance with some embodiments of the present disclosure. FIG. 11A illustrate a fan and duct assembly with flexible tubes; and FIG. 11B illustrate a fan and duct assembly under a seat and pulling air from movable thigh and side-bolster areas; and

FIG. 12 illustrates how the ribbon may be inserted with the links in the air channel and the heat exchangers spread out on the surface, which is an upside-down orientation of the ribbon when compared to FIGS. 9, 10, and 11, in accordance with some embodiments of the present disclosure.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

The term “adjacent” or “adjacent to,” as used herein, includes ‘next to’, ‘adjoining’, ‘in contact with’, and ‘in proximity to’. In some instances, adjacent components are separated from one another by one or more intervening layers. The one or more intervening layers may have a thickness less than about 10 millimeters (mm), 5 mm, 1 mm, 0.5 mm, 0.1 mm, 10 micrometers (“microns”), 1 micron, 500 nanometers (“nm”), 100 nm, 50 nm, 10 nm, 1 nm, 0.5 nm or less. Such thickness may be for the one or more intervening layers being in an uncompressed state. For example, a first layer adjacent to a second layer can be in direct contact with the second layer. As another example, a first layer adjacent to a second layer can be separated from the second layer by at least a third layer.

The present disclosure provides methods of producing thermoelectric strings and integrating thermoelectric strings within consumer products, such sitting or sleeping surfaces, including seats and beds. Such seats may be part of vehicles, such as cars, trucks, motorcycles, scooters, boats, airplanes, helicopters, and tanks. The present disclosure also provides configurations of thermoelectric strings and devices that include one or more thermoelectric strings.

### Durable Thermoelectric Devices

A thermoelectric string may comprise links that are operatively coupled together within a product. A string may have individual strands, such as at least 2, 3, 4, 5, 6, 7, 8, 9, 10, 20, 30, 40, 50, 100, 200, 300, 400, 500, 1000 or more strands. The strands may be wires.

The thermoelectric string may be inserted into the top layer of a surface, such as a surface of a product, so as to add heating and cooling to that surface. In some examples, the thermoelectric string may comprise links mounted on a strain relief. The thermoelectric strings may have conductors emanating upwards toward the surface to insert or remove heat. Additionally or alternatively, the thermoelectric strings may have conductors emanating downwards to a heat exchanger layer. The conductors may comprise stranded wires, for example, which may allow for expansion of the strands on the surface and/or the heat exchanger. Such expansion may be used to increase the surface area available for conducting heat on the object or person resting on the surface. Additionally, such expansion may increase the surface area for heat exchange via air flow. By not expanding the strands near the strain relief, backflow of heat may be better controlled.

The strain relief (or strain relief element) may be formed of various materials. In some examples, the strain relief is formed of a metallic or insulating material. The strain relief may be formed of a polymeric material or composite material. The composite material may be comprises of woven fiberglass cloth with an epoxy resin binder that may be flame resistant (self-extinguishing), such as FR-4. The strain relief may be formed of circuit board material. In some examples, the strain relief comprises glass fiber or epoxy.

In some examples of thermoelectric string designs, a 45 degree to 90-degree angle may be formed in the conductor as the thermoelectric string reaches the surface. In designs where the conductor is composed of stranded wire, the stranded wire may bend to accommodate this 45 degree to 90-degree angle as the conductor reached the surface. However, as the stranded wire is exposed to stress, the angle of bending may result in a breaking point in the wire. In some examples, stranded wire experience breaks at the angle that they are bent when they are repeatedly exposed to flexing, such as under cyclic stress. Examples of cyclic stress may occur from repeated flexing under cyclic stress by, for example, a person's repeated sitting or lying down on a seat and/or bed that includes a thermoelectric string near the surface.

In contrast to the thermoelectric string designs that have a bending angle as they approach the surface, devices as provided herein include thermoelectric strings having a T-shaped (or substantially T-shaped) design or configuration. In particular, the T-shaped design disclosed herein does not require a wire to be bent at 45 degrees to 90 degrees as the thermoelectric string approaches a surface. Instead, the wire strands may be terminated with a ferrule or splice band. As an alternative, the wire strands may be terminated without a ferrule or splice band. Such termination may be soldered at a 0 degree to 90 degree angle, 10 degree to 90 degree angle, 20 degree to 90 degree angle, 30 degree to 90 degree angle, 40 degree to 90 degree angle, or 45 degree to 90 degree angle relative to the board so as to relieve strain of the circuit board.

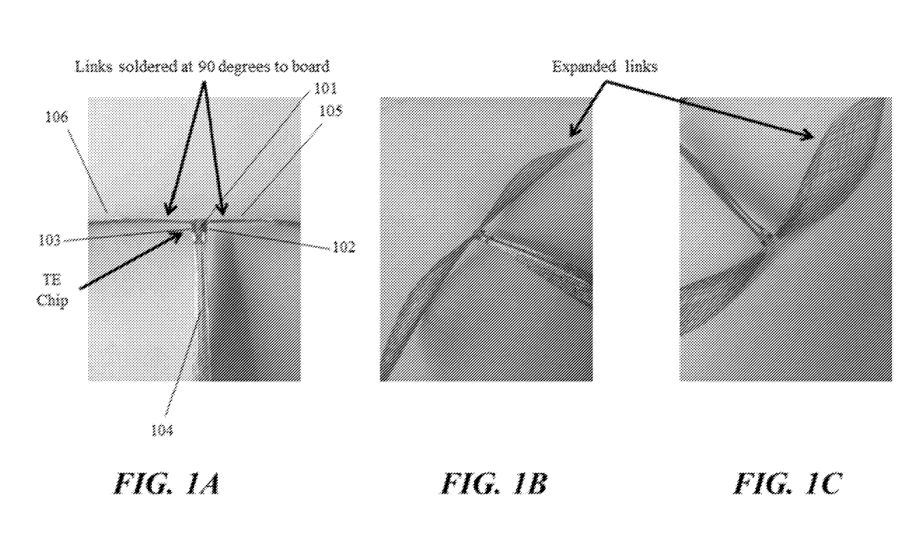

Accordingly, FIGS. 1A-1C show views of a T-shaped (or substantially T-shaped) configuration for the thermoelectric string wherein the lead-in and lead-out links are attached to the strain relief at a 90-degree angle. FIG. 1A illustrates a side view of a T-shaped configuration for the thermoelectric string, FIG. 1B illustrates an underneath view of a T-shaped configuration for the thermoelectric string, and FIG. 1C illustrates a top view of a T-shaped configuration for the thermoelectric string. Although the figures illustrate T-shaped configurations, other shapes are possible. For example, angles between individual wires may be from about 45 degrees to 90 degrees.

As provided in FIGS. 1A-1C, two thermoelectric chips, or elements, are mounted on either side of the strain relief circuit board. Stranded link wires may be converged into a ferrule at the end to hold the strands together. The terminated end of the wire is soldered to the board at a 90-degree angle to the board. In this embodiment, two links may be soldered to the board at right angles, making a T-shape. As such, the T-shaped design described in FIGS. 1A-1C may not require the wire to be bent at 90 degrees. Instead, after the thermoelectric string illustrated in FIG. 1A is inserted into the top layer of foam or other insulating panel, the links may be located along the surface of the panel. The wire strands 105 and 106 may be terminated with a splice band, and this termination may be soldered at a 90-degree angle to the strain relief 101 on which is mounted n and p type thermoelectric elements 102 and 103, respectively. These links may be expanded away from the strain relief as shown in FIGS. 1B and 1C to provide more uniform heating or cooling to the surface. The heat-exchanger wire 104 may be inserted vertically into a hole in the foam or other seating or bedding material. When the seat or bed surface is compressed, the T-shaped configuration in FIGS. 1A-1C may move vertically up and down with minimal bending of the wires.

The wire strands 105 and 106 may provide for improved heat transfer. In some examples, the wire strands 105 and 106 permit improved heat transfer to or from a fluid (e.g., air) that comes in contact with the wire strands 105 and 106. The wire strands 105 and 106 may be distributed on a surface of a panel, such as an insulating panel.

A thermoelectric string may include alternating p-type 102 and n-Type 103 thermoelectric elements, which may be connected by lengths of braided or stranded wire. The thermoelectric elements may comprise metals, although non-metallic conductors such as graphite and carbon may be used. In some embodiments, the alternating elements can be small crystals of, e.g., Bismuth Telluride (n-type) 103 and, e.g., Antimony Bismuth Telluride (p-type) 102, in some cases plated with, e.g., nickel and/or tin on the ends to facilitate solder connections, or small thermo-tunneling vacuum tubes. Because the thermoelectric elements or tubes may be fragile, the strain relief may prevent a pulling force on the wire from breaking the elements. The aggregate diameter of the stranded or braided wire may be designed to carry the desired electrical current with minimal resistance. Other examples of configurations of thermoelectric strings that may be used with methods, devices and systems of the present disclosure are provided in U.S. Pat. No. 8,969,703 to Makansi et al. (“Distributed thermoelectric string and insulating panel”), which is entirely incorporated herein by reference.

The stranded wires below the strain relief in FIG. 1A may reach beyond the panel to an airflow layer, or other heat exchanger, below the panel. This heat exchange process may benefit from larger surface area of metal may occur by expanding the stranded wires below the strain relief as shown in FIG. 1B. Additionally, the effectiveness of surface heating and cooling may also benefit from the stranded wires, or other conductors, used from the links and loops to be compacted inside the panel to prevent backflow of heat from the warm side to the cold side.

In an example, a thermoelectric string is built and durability-tested with a machine simulating the addition and removal of a 160-pound person's weight 100,000 times, and the thermoelectric string is fully functional at the end of the test.

### Smoothness and Softness

Thermoelectric devices and systems of the present disclosure can include a panel with thermoelectric strings adjacent to a pad. The pad may be formed of various materials, as described elsewhere herein. The pad may be a thermally and/or electrically insulating panel. In some cases, the pad may be thermally conductive. In some cases, one or more additional layers may be adjacent to the pad, such as, for example, a cover.

In the evaluation of a seat or bed surface, a potential customer may rub a hand along the surface expecting to feel softness and smoothness. The softness and smoothness feel by hand may be related to the buyer's perception of comfort and quality. As such, the automotive and seating industries have often included a “plus pad” underneath the cover, which is a thin, soft foam layer. Even underneath a leather cover, this foam pushes the leather upwards, creating a soft feel when touched or rubbed such as by a potential customer's hand. In addition, this thin soft foam layer may be used to hide irregularities in the firm foam underneath, thereby creating a smoothness feel.

The inclusion of a foam plus pad with a distributed thermoelectric panel diminishes performance because soft foams are very insulating. In view of this, other materials may be used as plus pads. For example, conductive (e.g., graphite) particles may be added to foam that may be used as a plus pad. In other examples, visco-elastic foam, which collapses more than standard foam, may be used as a plus pad. In additional examples, a combination visco-foam with conductive particles may be added to foam, or other materials, that may be used as a plus pad. As such, these materials may increase the thermal conduction of a plus pad while maintaining the soft and smooth feel by hand at the surface over the cover.

Provided herein are several examples of materials that may be used as the plus pad layer just beneath a seat cover. In some examples, the seat cover may be leather. Without limitation, these examples may be applied to products such as beds, office chairs, sofas, easy chairs, auto seats, truck seats, wheelchair cushions, and medical surfaces where it may be desirable for a plus pad to be used to maximize thermal conduction when the surface is occupied.

In some examples, a soft and smooth feel of a product may be accomplished by using a plus pad and that has a large amount of air when not under pressure (e.g., during hand feel), but that also expels a significant amount of air when the plus pad is under the pressure or weight of a body sitting or lying down on the surface. In some examples, a plus pad may expel an amount of air that represents at least 20%, 25%, 30%, 35%, 40%, 45%, 50%, 55%, 60%, 65%, 70%, 75%, 80%, 85%, 90%, 95%, 98%, 99%, or more than 99% of its volume when the plus pad is in a resting position. However, standard foam does not expel enough of the air under pressure than a similar amount of standard foam, resulting in less thermal conduction. The materials disclosed herein expel more air under pressure, or include other conductive particles or a combination of these, resulting in greater thermal conduction. These materials disclosed herein are tested for thermal intensity when used as a plus pad in a heated and/or cooled seat. These materials are also tested for smoothness and softness during a hand feel. The materials performed better in these tests than standard polyurethane foam or standard viscoelastic foam.

A foam pad may have various thicknesses. In some examples, the foam pad has a thickness from about 0.1 millimeter (mm) to 100 mm, or 1 mm to 50 mm, or 5 mm to 10 mm. Such thickness may be for the foam pad being in an uncompressed state.

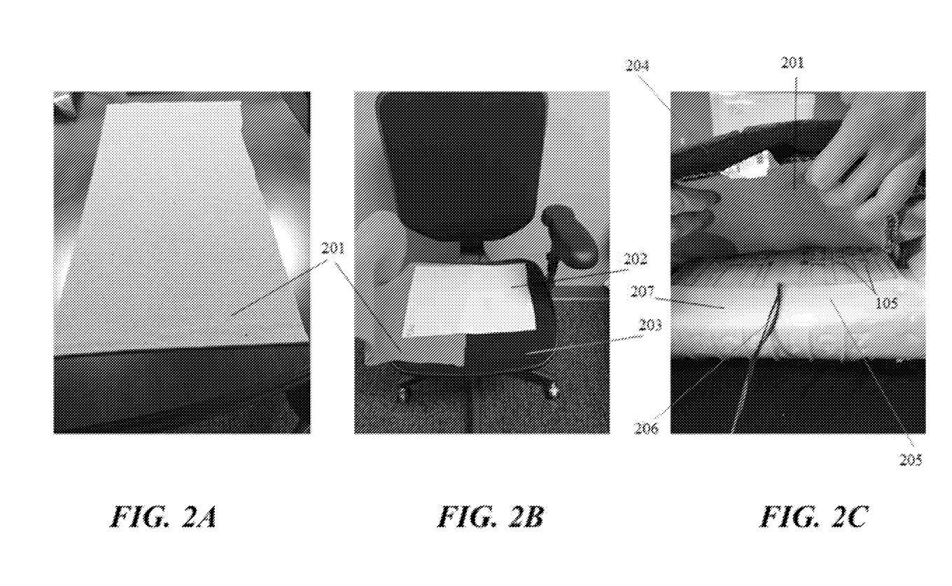

Accordingly, FIGS. 2A-2C show views of a diamond particle-infused viscoelastic foam as a plus pad. FIG. 2A illustrates a diamond-infused viscoelastic foam pad that is 6 millimeters (mm) in thickness, FIG. 2B illustrates an apparatus for measuring hand feel and thermal transmission, and FIG. 2C illustrates a foam pad (e.g., viscoelastic foam pad) that is integrated in an automotive seat cover. The foam pad may be sewn into the automotive seat cover. Diamond has higher thermal conductivity than graphite, and use of diamond is now both available and affordable. The material illustrated in FIGS. 2A-2C may be, for example, slow-recovery viscoelastic foam. The same particle infusion may be applied to other types of foam, such as, for example, standard polyurethane foam, latex foam, foam rubber, or other similar material.

FIG. 2B shows an apparatus that may be used to test the hand feel and the thermal transmission of this material. The chair 203 has the cooling and heating built-in using a thermoelectric ribbon (not shown in FIG. 2B). This chair has a very thin black cover. In this apparatus, the plus pad 201 is placed on top of the temperature controlled surface of the chair 203, and then a leather sheet 202 is placed on top of the plus pad. This stack simulates an automotive seat construction. The plus pad 202 is located in half the seat surface, allowing for simultaneous comparison by the occupant of this plus pad with no plus pad, as shown in FIG. 2B, or with another plus pad material. This simultaneous comparison facilitates both hand-feel and thermal transmission. In thermal transmission testing, the heating or cooling of the chair is turned on, and the occupant sits with half of the torso on top of the material under test (in this case the diamond-infused visco foam and a control configuration.

With the apparatus in FIG. 2B, test results revealed a comparable hand-feel for diamond vs. graphite infused viscoelastic foam of the same thickness of 6 mm, but the diamond foam had slightly better thermal transmission than graphite foam. Because of these good results of the test, this material may be selected for integration into the build of automotive seats. FIG. 2C illustrates the 6 mm viscoelastic foam plus pad 201 sewn into the leather cover 204 and then the new cover is placed over the foam bun 205 and 207 that has an integrated thermoelectric string with links 105 and power connector wires 206. The foam plus pad 201 may have greater softness than the base seat foam 205 and 207 in order to make the surface feel soft to the touch, but still support the weight of an individual. The foam plus pad 201 may also have the ability to bulge out, such as bulge out of the leather, which may, for example, give the seat a new appearance for a longer period of time and help avoid a deflated or worn appearance.

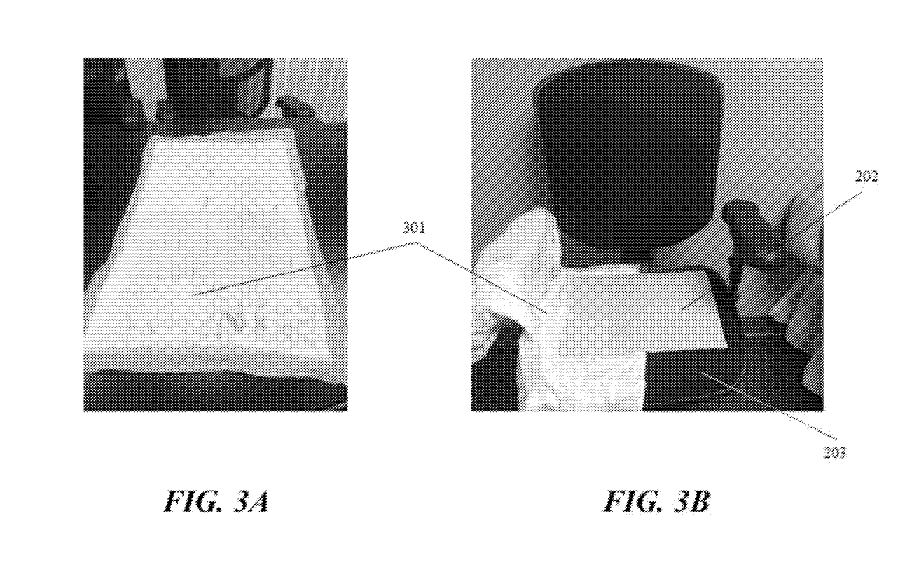

FIGS. 3A-3B show views of a continence pad of polyester fill and an apparatus for testing its functionality as a pad between a leather seat cover and the seat surface containing the thermoelectric string. FIG. 3A shows a continence pad 301 used as a plus pad for seating. The continence pad may polyester fibers (e.g., bundled polyester fibers) in a thin batting normally used for absorbing body fluids. Under pressure of a body sitting or lying down, the fibers compress to tightly packed and achieve higher thermal conduction than compressed standard foam. This material may be tested in the same apparatus, as shown in FIG. 3B, with a heated and cooled office chair 203 and a leather cover 202. The results indicated this material 301 had an acceptable hand-feel as well as thermal transmission.

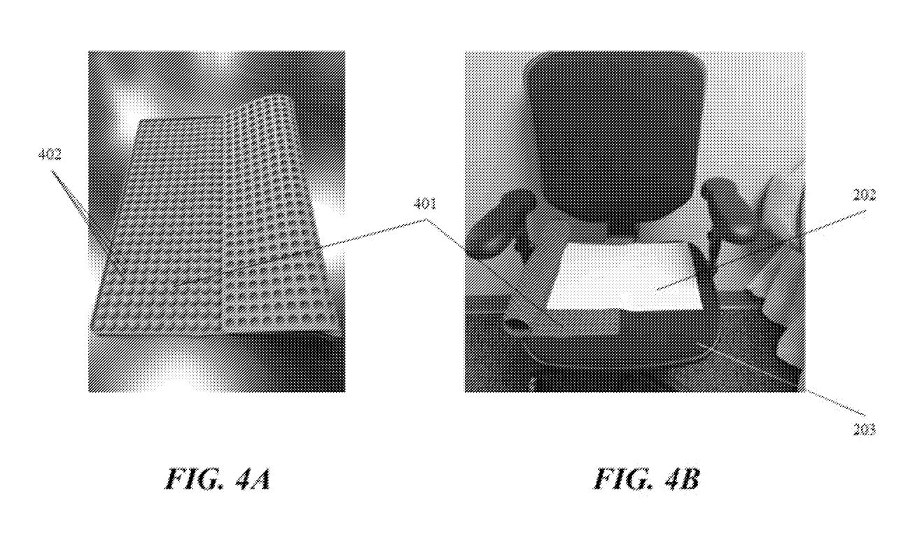

FIGS. 4A-4B show views of an embossed sheet and an apparatus for testing its functionality as a pad between a leather seat cover and the seat surface containing the thermoelectric string. The embossed sheet may be flexible. The embossed sheet may be formed of a polymeric material, such as rubber. Centers of the embossed sheet may be separated by a distance from about 0.1 mm to 100 mm, or 1 mm to 50 mm, or 3 mm to 10 mm.

FIG. 4A illustrates a thin and soft sheet (e.g., rubber sheet) that has been embossed with a circular array pattern. The embossed hemispheres 402 “puff up” a leather cover that is placed over it, but flatten out under the pressure of a person sitting. When flat, this material's thermal transmission ability reverts to that of an un-embossed sheet of the same material. The diameter of the hemispheres 402 may be selected to be small enough to reduce the hand-feel granularity with the leather cover to provide a smooth, and not lumpy, feel. This material shows promise as a plus pad, because the sheet material may be infused with conductive particles, and may be thin enough to provide maximum thermal transmission when flattened. The height of the hemispheres may be selected to achieve puffing up amount. Without limitation, this material may be silicone, neoprene, urethane, and the infused particles may be oxides, graphite, diamond or similar. FIG. 4B shows a similar apparatus for evaluating the hand-feel and thermal transmission of the embossed sheet 401 in combination with a leather cover 202 and a chair 203 with heating and cooling capability.

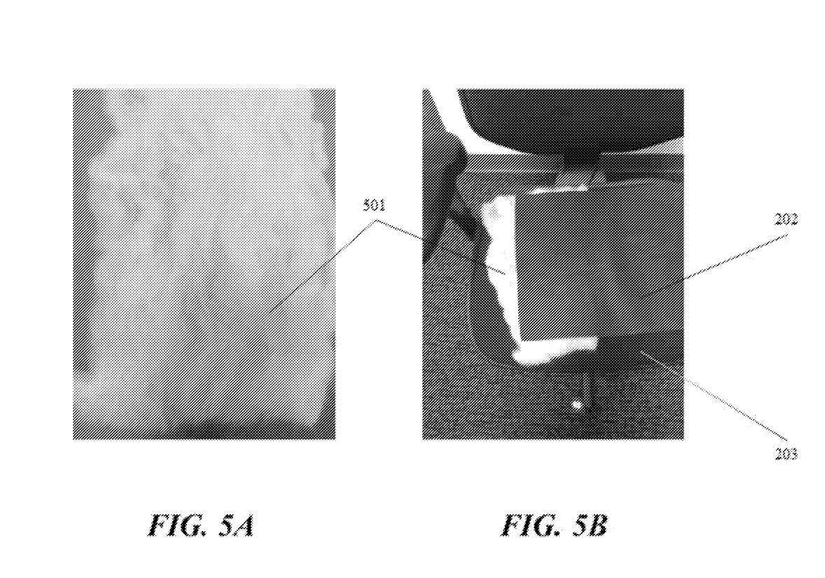

FIGS. 5A-5B show views of a loose bunch of lamb's wool and an apparatus for testing its functionality as a pad between a leather seat cover and the seat surface containing the thermoelectric string. FIG. 5A shows lamb's wool as a material for a plus pad. Lamb's wool may be used in seating, for example, in the pilot's seat in an airplane, and may have the durability and other characteristics needed for such a seat. Lamb's wool is soft, and creates a smooth surface when used as a plus pad. Furthermore, lamb's wool collapses under pressure wherein the raw fibers become closely packed, providing a higher thermal conduction. FIG. 5B shows the same apparatus for evaluating the hand-feel and thermal transmission of the lamb's wool 501 employing the leather cover 202 and the heated and cooled chair 203. The test results indicate that this material is effective in both hand feel and thermal transmission for a leather-covered automotive seat.

Although FIGS. 5A and 5B have been described in the context of lamb wool, other types of wool may be used. For example, the wool may be sheep wool or goat wool.

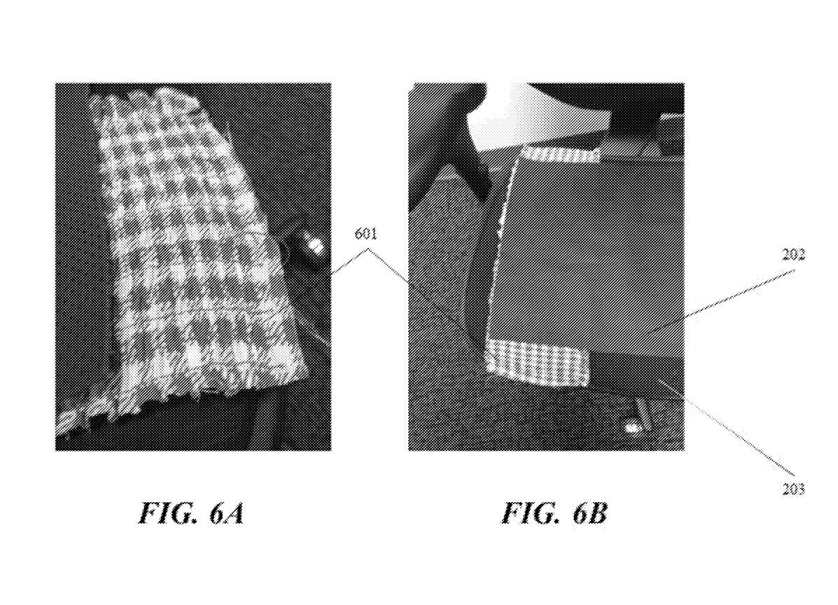

FIGS. 6A-6B show views of a stretchy corrugated textile and an apparatus for testing its functionality as a pad between a leather seat cover and the seat surface containing the thermoelectric string. FIG. 6A shows a special textile fabric 601 with pre-stretched woven elastic fibers. This material is used for the mid-section of a girl's dress, and is available from JoAnn's and other fabric stores. The elastic fibers cause the fabric to scrunch up, providing a corrugated layer with lots of air. Under pressure, the air is expelled and the thin textile is flattened or folded, leaving only a thin textile layer that is very conductive. FIG. 6B shows an apparatus for testing the hand feel of this material 601 using a leather cover 202 and a heated and cooled chair 203. The test results indicate that this material is effective in both hand feel and thermal transmission for a leather-covered automotive seat.

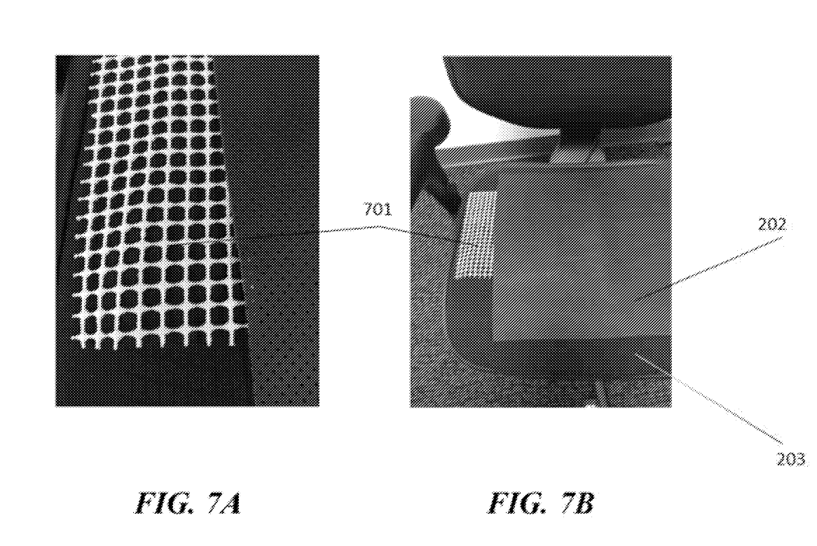

FIGS. 7A-7B show views of a non-slip pad and an apparatus for testing its functionality as a pad between a leather seat cover and the seat surface containing the thermoelectric string. FIG. 7A shows a porous mesh of skinned foam 701, which may be used to prevent slipping. This material may be designed to have voids small enough to not be felt when covered by another layer, and the ratio of material volume to air volume is low. The void may have various shapes, such as circular, triangular, square, rectangular, pentagonal, or hexagonal, or partial shapes or combinations of shapes thereof. In the illustrated example, the voids are square or square-like. Under the compression of a person sitting, the voids in this material dominate the thermal transmission, and hence these void areas provide the full thermal transmission as with no material. FIG. 7B shows an apparatus for testing the hand feel of this material 701 using a material (e.g., leather) cover 202 and a heated and cooled chair 203. The test results indicate that this material is effective in both hand feel and thermal transmission for a covered (e.g., leather-covered) automotive seat.

Plus pads as illustrated in FIGS. 2A through FIG. 7B may be covered with a low friction sheer layer or fabric, and another such sheer layer or fabric may be placed over the surface supporting the plus pad. The low friction sheer layer may have a coefficient of friction less than or equal to about 2, 1.5, 1, 0.5, 0.1, or 0.01 at 25° C. The sheer layer or layers may allow the cover materials to slide relative to the surface materials, thereby reducing the stress on the foam and thermoelectric ribbon during disturbances that have lateral forces. On example of this disturbance is ingress/egress of a person in an automobile seat. The automotive industry requires a test of 50,000 cycles of this disturbance for automotive seats with or without climate systems.

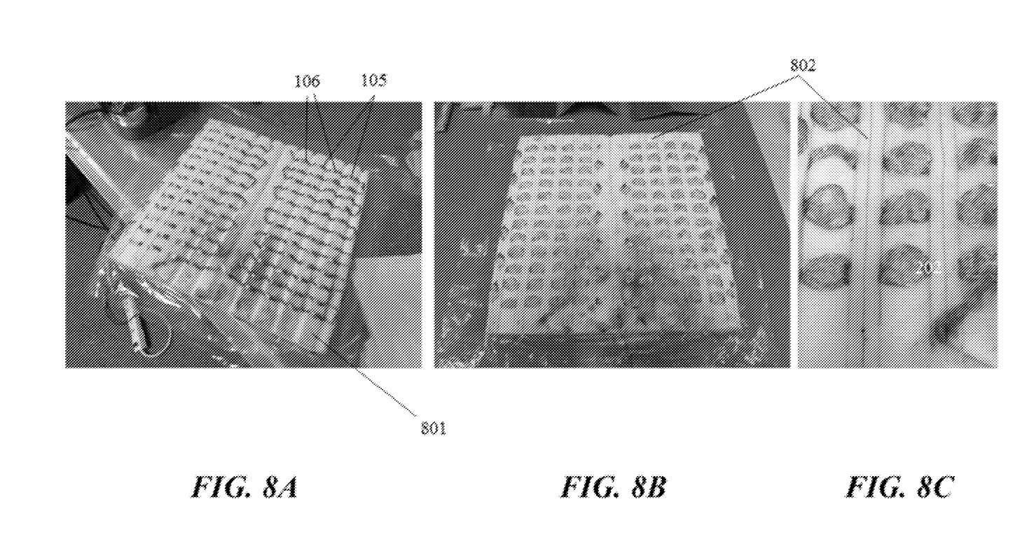

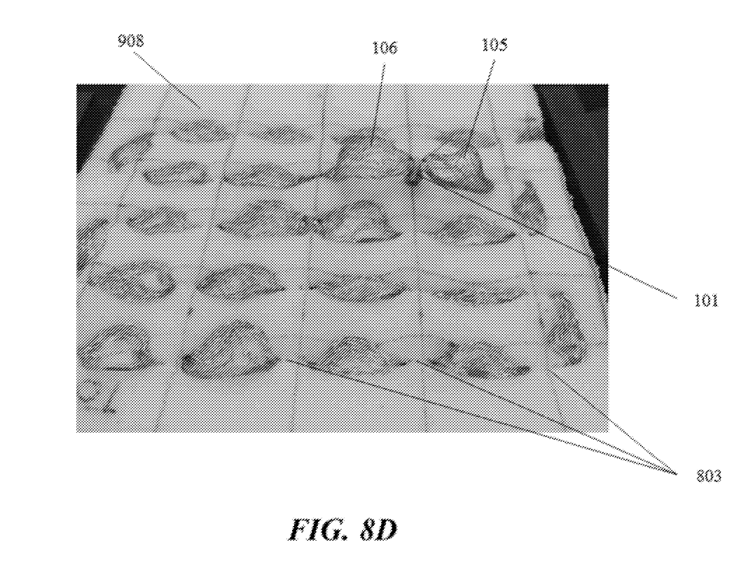

FIGS. 8A-8D show views of a method of cutting strips and forming trenches in the foam prior to insertion of the thermoelectric string, and then re-inserting the strips to cover the thermoelectric strings. FIGS. 8A-8D shows a method for combining the thermoelectric string with the foam of the seat or bed and simultaneously accomplishing (1) electrical insulation between the lead-in links 106 and the lead out links 105, and (2) providing a soft foam cover 802 to hide the lumpiness of the thermoelectric strings. First, strips of foam are removed from the surface, leaving behind trenches 801 in FIG. 8A. The thermoelectric string is inserted into the foam with the elements placed just under the trench 801 and the links 105 and 106 routed from one trench to the next. After placement of the thermoelectric string, the removed strips are re-inserted in their original locations as shown in FIGS. 8B and 8D. FIG. 8D illustrates re-glued foam with angled slits 803 between links to prevent a short circuit. The strain reliefs may be inserted into the slits and the slits may be subsequently glued back together between the wire links to prevent a short circuit. The re-glued slit may not present a rigid member for the wires to bend against, which may be an improvement over FIGS. 8A-8C. The ability of the stranded wires to bend against a rigid glue line has been shown to reduce the number of sit-down cycles of durability of the assembly over the lifetime of the product. Over time and sit-down cycles, the wires can break at the intersection of the wires and a glue line, which may lead to equipment failure.

### Fluid Flow System Integration

This present disclosure also provides fluid flow systems that may carry heat away from the heat exchangers in the thermoelectric string. Such flow systems may be integrated with various media, such as automotive seats. The fluid flow system may direct the flow of a gas, such as air, or other cooling and/or heating fluid, such as a cooling liquid.

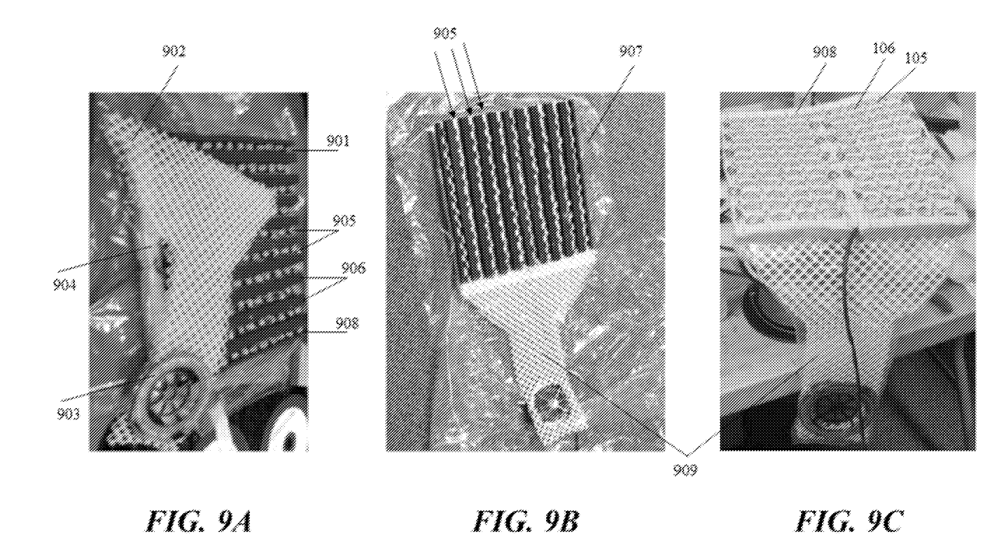

FIGS. 9A-9C show views of linear channels for fluid flow along the heat exchangers is mated with a sealed spacer mesh material that allows the fluid flow path to be routed underneath the seat and a fan mount for a fan to pull the fluid. FIG. 9A shows how the distributed thermoelectric assembly may be integrated into the seat manufacturing process. The components needed for making this assembly are the thermoelectric string 908, spacer mesh 902 for mating with the linear channels, spacer mesh 909 for flexibly ducting a fluid (e.g., air) to a location convenient for mounting the fan, linear channel walls 906 and channels 905 formed of firm foam, insulating layer 904 made from seat foam, heat exchangers 901 of the thermoelectric string placed in the channels 905, and links 106, 105 of the thermoelectric string placed along the surface of the seat foam layer. The linear channels 905 may allow for unobstructed flow of a fluid (e.g., air) along the heat exchangers 905 from an inlet 908 that is continued to the external environment. Without limitation, the linear channel walls 906 may be replaced by an array of pillars. The fluid may be pulled from the inlet 908 through the channels 905 by a fan (not shown) that is mounted on a fan mount 903. The entire fluid flow path may be sealed by plastic sheeting 907 except for the inlet 908 and the outlet at the fan mount 903. The spacer mesh provides an un-collapsible yoke to route the fluid flow through a vertical slit in the seat foam. Once routed, the fan mount may be attached to the underside or back side of the seat cushion, and the fluid may then be ducted from the fan outlet to the external environment.

In some cases, it is desirable to have some fluid flow (e.g., air flow) laterally just beneath holes in the cover in order to wick away, or evaporate, a fluid on or adjacent to the user when sitting down, such as perspiration. For example, FIG. 7A shows a leather cover with holes that are taken from a seat with ordinary convection ventilation. In order to provide such ventilation in combination with the device and features of FIG. 9, an array of holes may be arranged in the seat foam 904 in FIG. 9A that extend from the surface with the links 105 and 106 down to the fluid flow channels 905. Then, the holes in the cover may also be used as inlets for the fluid flow system, and the presence of a dry fluid (e.g., dry air) below the holes in the surface may provide evaporation of perspiration or other moisture on the surface. Without limitation, the plus pads of FIGS. 2-7 may also have holes to aid in this process, in some cases aligned with the holes in the seat foam.

Without limitation, the thermoelectric string exposed in FIGS. 8A-8D and FIGS. 9A-9C may have been inserted such that the loops of the ribbon inside the insulating foam are situated at either about 90 degrees, as in the configuration of FIG. 1, or at about 45 degrees to the plane of the foam. In the case of 45 degrees to the place of the foam, the loops may also be at a complex angle relative to the line of the links A bed of hollow nails may be employed to temporarily house the loops for ease of insertion of the ribbon into the foam. As an alternative, the holes in the insulating foam may be formed, at any desired angle, using molding or punching or drilling. In the case of punching, the angled holes may be formed by having the punches oriented at an angle or by shifting and stressing the foam laterally as needed such that a vertically punched hole becomes the desired angled hole when the foam relaxes.

Also, without limitation, the insert of FIGS. 8A-8D and 9A-9C may be placed in the seat with a 90, 180, or 270 degree rotation relative to the seat, for purposes of fitment, desired location of the gas flow path and fan, or for greater durability in the presence of lateral disturbances from ingress/egress of the driver or passenger.

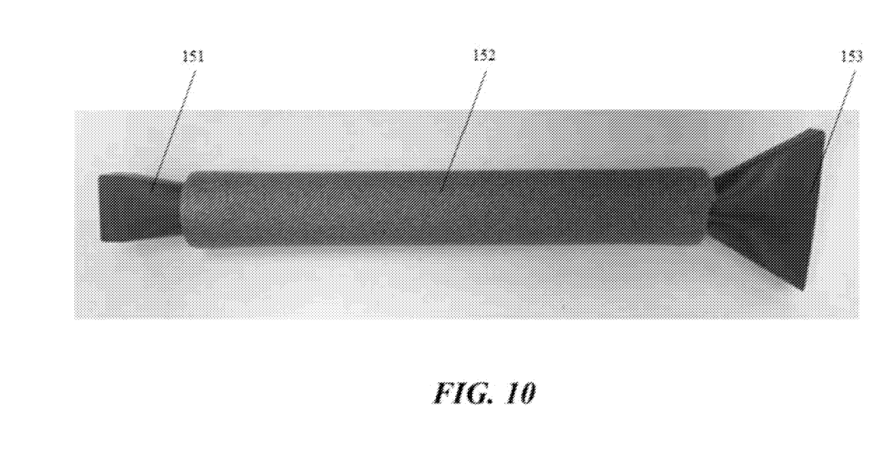

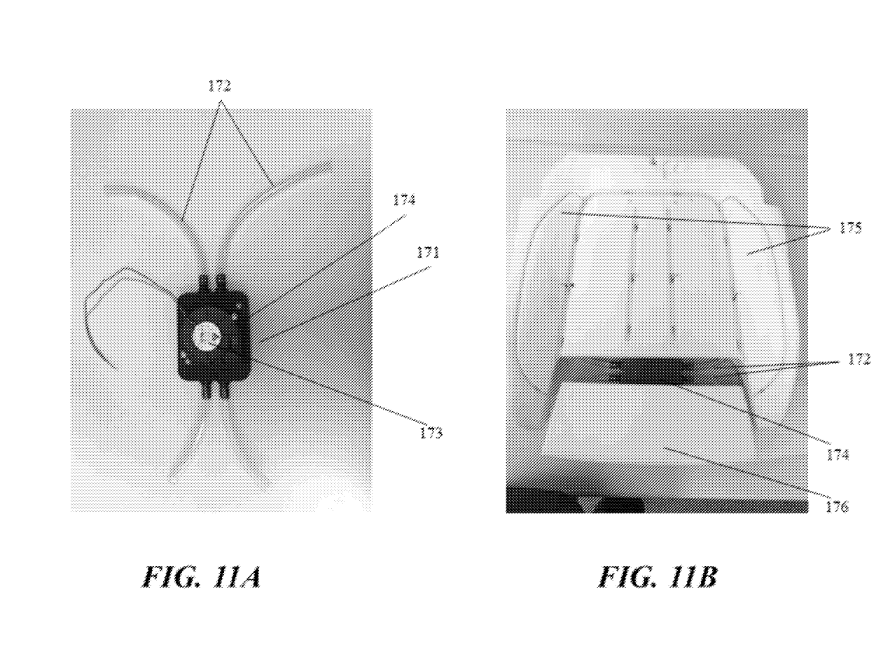

FIG. 10 shows an assembly for routing a gas (e.g., air) from the fan outlet to a desired exit to the ambient environment. The fan duct 151 attaches to the outlet of the fan and connects to a foam tube 152 which in turn is connected to an exit duct 153 from which the gas is routed to the desired exit location. Typically, the exit is to the back seat area of an automobile. The foam tube 152 also has the desirable property of absorbing noise from the fan and from the gas flow.

FIGS. 11A-11B show views of a fan and duct assembly with flexible tubes to pull a gas (e.g., air) from multiple sections of the seat, including moving sections. FIG. 11a shows a gas flow (e.g., air flow) assembly that can accommodate moving portions of a seat cushion. In some situations, in automobiles, the bolster areas 175 of the cushion are adjustable for maximum comfort and body stability when driving or riding on curves in the road. Also the thigh support areas 176 can move in or out to accommodate persons of different sizes. In addition, car manufacturers may wish to have heating and cooling built into these parts of the seat. FIG. 11A shows a gas flow assembly 171 that can accommodate these motions. A fan 173 pulls a gas through a manifold 174 and further through flexible tubes 172. The multiple tubes provide suction to each movable part of the seat that contains a thermoelectric string and gas flow layer (string is not shown in FIG. 11B).

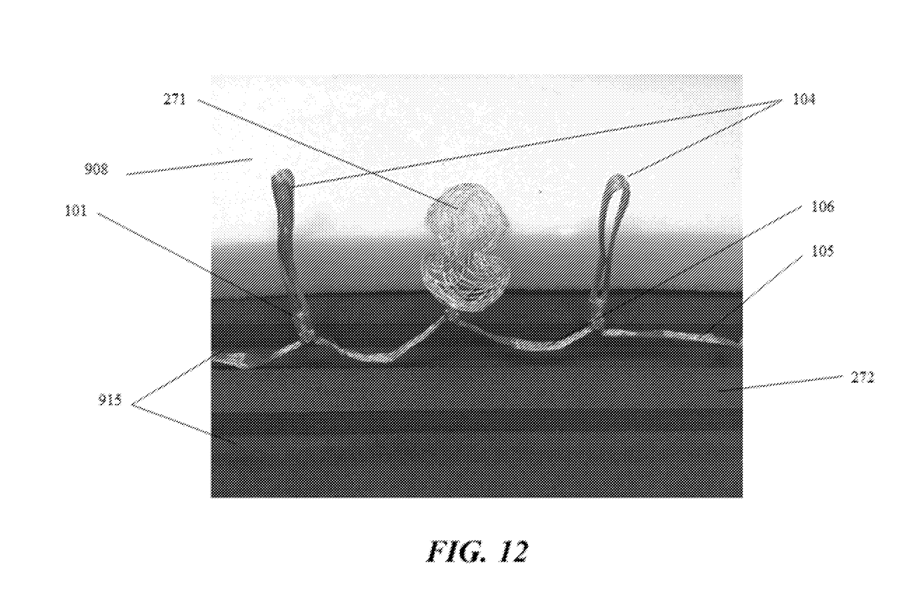

FIG. 12 illustrates the manner in which a ribbon may be inserted with the links in the channel and the heat exchangers spread out on the surface, which is an upside-down orientation of the ribbon when compared to FIGS. 9A-9C, 10, 11A, and 11B. A loop wire 271 is now spread out on the surface of the seating material 908. For reference, the loop wires prior to spreading are also shown 104. The links 105 and 106 now are bowed into the channel to act as heat exchangers. The channels may be formed by linear cavities 915 bordered by linear walls 272. In FIG. 12, the strain relief assembly 101 may be oriented at an acute angle, complex acute angle, or right angle relative to the surface of the seating material 908. The angle may be from about 10° to 90°, or 25° to 90°. In FIG. 12, the ribbon is shown in front of the seating material for visual understanding, and in the actual embodiment the strain relief assemblies 101 may be inserted into slits or holes in the seating material

Thermoelectric devices, systems and methods of the present disclosure may be combined with or modified by other thermoelectric devices, systems or methods, such as those described in, for example, U.S. Pat. No. 8,969,703 to Makansi et al. (“Distributed thermoelectric string and insulating panel”), which is entirely incorporated herein by reference.

While preferred embodiments of the present invention have been shown and described herein, it will be obvious to those skilled in the art that such embodiments are provided by way of example only. It is not intended that the invention be limited by the specific examples provided within the specification. While the invention has been described with reference to the aforementioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations or equivalents. It is intended that the following claims define the scope of the invention and that methods and structures within the scope of these claims and their equivalents be covered thereby.

1. A thermoelectric device, comprising:
a panel comprising an electrically and thermally insulating material; and
a thermoelectric string comprising a plurality of thermoelectric elements mounted on a strain relief element within said panel, wherein said thermoelectric elements comprise an n-type thermoelectric element and a p-type thermoelectric element electrically coupled to one another in series, wherein said thermoelectric string is (i) compacted in cross section inside said panel and (ii) expanded in cross section outside said panel, and wherein said strain relief element permits said thermoelectric string to be movable in proximity to said strain relief element.

2. The thermoelectric device of claim 1, wherein said thermoelectric string is secured to said panel in the absence of an adhesive.

3. The thermoelectric device of claim 1, further comprising an additional strain relief element within said panel, wherein said thermoelectric string is mounted on said additional strain relief element.

4. The thermoelectric device of claim 3, wherein said thermoelectric string is threaded into said additional strain relief element through an opening to permit said thermoelectric string to rotate with respect to said additional strain relief element.

5. The thermoelectric device of claim 3, further comprising a plurality of additional thermoelectric elements mounted on said additional strain relief element, wherein said additional thermoelectric elements comprise an n-type thermoelectric element and a p-type thermoelectric element electrically coupled to one another in series, and wherein said additional thermoelectric elements are in electrical communication with said plurality of thermoelectric elements mounted on said strain relief panel.

6. The thermoelectric device of claim 1, wherein said n-type thermoelectric element is electrically coupled to said p-type thermoelectric element through a stranded wire in said panel.

7. (canceled)

8. (canceled)

9. The thermoelectric device of claim 1, wherein said thermoelectric string comprises stranded wires with opposing ends that are each terminated by a termination element to maintain compaction of said stranded wires.

10. (canceled)

11. (canceled)

12. The thermoelectric device of claim 1, wherein said thermoelectric string is threaded into said strain relief element through an opening in said strain relief element, which opening permits said thermoelectric string to rotate with respect to said strain relief element.

13. (canceled)

14. The thermoelectric device of claim 1, further comprising an intermediate pad adjacent to said panel and a cover adjacent to said intermediate pad.

15. The thermoelectric device of claim 14, wherein said intermediate pad has an uncompressed thickness between about 5 millimeters and 10 millimeters.

16. The thermoelectric device of claim 14, wherein said intermediate pad comprises viscoelastic foam, polyester fibers and/or carbon particles.

17. (canceled)

18. The thermoelectric device of claim 14, wherein said intermediate pad is a flexible sheet with centers that are spaced apart from 3 millimeters to 10 millimeters.

19. (canceled)

20. (canceled)

21. (canceled)

22. (canceled)

23. (canceled)

24. (canceled)

25. The thermoelectric device of claim 14, further comprising an additional layer between said intermediate layer and said cover, wherein said additional layer permits said cover to move relative to said intermediate layer.

26. The thermoelectric device of claim 1, wherein said strain relief element is disposed in a trench among a plurality of trenches in said panel.

27. (canceled)

28. The thermoelectric device of claim 1, wherein said strain relief element is disposed in a linear slit among a plurality of slits in said panel.

29. (canceled)

30. The thermoelectric device of claim 1, further comprising a fluid flow system comprising channels adjacent to said panel.

31. (canceled)

32. (canceled)

33. (canceled)

34. (canceled)

35. The thermoelectric device of claim 30, further comprising a plurality of thermoelectric strings including said thermoelectric string in said channels, which plurality of thermoelectric strings includes wires spread out on a surface of said panel.

36. The thermoelectric device of claim 1, further comprising a plurality of thermoelectric strings including said thermoelectric string, wherein each of said plurality of thermoelectric strings comprises a plurality of thermoelectric elements mounted on a given strain relief element within said panel.

37. The thermoelectric device of claim 1, wherein said panel comprises holes that are directed from a first side of said panel to a second side of said panel, wherein said second side is adjacent to an air flow layer, wherein said holes permit a fluid to flow from said first side to said second side to mix with air in said air flow layer.

38. A method for forming a thermoelectric device, comprising:
(a) generating a trench or linear slit in a panel comprising an electrically and thermally insulating material; and
(b) providing a thermoelectric string comprising a plurality of thermoelectric elements mounted on a strain relief element within said trench or linear slit, wherein said thermoelectric elements comprise an n-type thermoelectric element and a p-type thermoelectric element electrically coupled to one another in series, wherein said thermoelectric string is (i) compacted in cross section inside said panel and (ii) expanded in cross section outside said panel, and wherein said strain relief element permits said thermoelectric string to be movable in proximity to said strain relief element.

39. The method of claim 38, wherein (b) comprises securing said thermoelectric string to said panel without the use of an adhesive.

40. The method of claim 38, wherein (a) comprises generating a plurality of trenches or linear slits in said panel, which plurality of trenches or linear slits includes said trench or linear slit.

41. The method of claim 38, wherein (b) comprises providing a plurality of thermoelectric strings including said thermoelectric string, wherein each of said plurality of thermoelectric strings comprises a plurality of thermoelectric elements mounted on a given strain relief element within said panel.

42. The method of claim 38, further comprising (i) providing an intermediate pad adjacent to said panel, and (ii) providing a cover adjacent to said intermediate pad.

43. The method of claim 38, wherein (b) comprises (i) mounting said thermoelectric elements on said strain relief element and (ii) inserting said strain relief element in said panel.

44. The method of claim 38, wherein (a) comprises removing a select portion of said panel to generate said trench or linear slit, and (b) comprises providing a portion of said thermoelectric string in said trench or panel.

45. The method of claim 44, further comprising replacing said selection portion over said portion of said thermoelectric string provided in said trench or linear slit.
